(19) United States
(12) Patent Application Publication
(10) Pub. No.: US 2006/0092679 A1
(43) Pub. Date: May 4, 2006

(54) Array substrate, method of inspecting the array substrate and method of manufacturing the array substrate

(76) Inventors: Masaki Miyatake, Kitaadachi-gun (JP); Mitsuhiro Yamamoto, Fukaya-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/294,547

(22) Filed: Dec. 6, 2005

Related U.S. Application Data
(63) Continuation of application No. PCT/JP04/07989, filed on Jun. 2, 2004.

(30) Foreign Application Priority Data
Jun. 6, 2003 (JP) 2003-162203

(51) Int. Cl. G11C 5/02; G02F 1/1343

(52) U.S. Cl. 365/51; 349/143; 349/139

(57) ABSTRACT

An array substrate comprising a substrate on which a plurality of scanning lines and a plurality of signal lines are arranged so as to intersect each other, pixel sections formed on the substrate and including an auxiliary capacitor and a switching element which is located close to each of intersections of the scanning lines and the signal lines, a regulation pad group provided to supply or output a signal to the scanning lines and the signal lines, a line made of metal and formed inside the substrate and along a periphery thereof, and a mark formed within a width region of the line by extracting part of a metal portion.

### CROSS-REFERENCE TO RELATED APPLICATIONS

This is a Continuation Application of PCT Application No. PCT/JP2004/007989, filed Jun. 2, 2004, which was published under PCT Article 21(2) in Japanese.

This application is based upon and claims the benefit of priority from prior Japanese Patent Application No. 2003-162203, filed Jun. 6, 2003, the entire contents of which are incorporated herein by reference.

### BACKGROUND OF THE INVENTION

1. Field of the Invention

This invention relates to an array substrate, a method of inspecting the array substrate and a method of manufacturing the array substrate.

2. Description of the Related Art

A liquid crystal display panel is used in various display units such as a display unit of a notebook personal computer (notebook PC), that of a cellular phone, and that of a television set. The liquid crystal display panel includes array substrate in which a plurality of pixel electrodes are arranged in matrix, opposed substrate having opposed electrode opposed to the pixel electrodes, and a liquid crystal layer held between each of the array substrate and its opposed substrate.

The array substrate has a plurality of pixel electrodes arranged in matrix, a plurality of scanning lines arranged along the rows of the pixel electrodes, a plurality of signal lines arranged along the columns of the pixel electrodes, and a plurality of switching elements arranged close to the intersections of the scanning lines and the signal lines. Further, a plurality of pads are arranged on some of the array substrate so that they are electrically connected to the scanning lines and the signal lines.

In general, a plurality of array substrates are formed on a mother substrate the size of which is larger than that of each of the array substrates. Alignment marks are formed on the mother substrate and located outside the array substrates to detect the positions of the array substrates. For example, as disclosed in Jpn. Pat. Appln. KOKAI Publication No. 2003-4588, the alignment marks are used to determine reference positions of the array substrates when the array substrates are inspected. The alignment marks are confirmed by viewing them displayed on a monitor.

As described above, a plurality of array substrates are formed on the surface of the mother substrate. If, however, the alignment marks are formed, the interval between the array substrates formed on the surface of the mother substrate is lengthened. This means that the area of the mother substrate is not used efficiently.

This invention has been developed in consideration of the above and its object is to provide an array substrate, a method of inspecting the array substrate and a method of manufacturing the array substrate in which a plurality of array substrates can be formed on a mother substrate at very narrow intervals and the positions of the array substrates can be confirmed even in this formation.

### BRIEF SUMMARY OF THE INVENTION

In order to attain the above object, according to an aspect of the present invention, there is provided an array substrate that includes a substrate on which a plurality of scanning lines and a plurality of signal lines are arranged so as to intersect each other; pixel sections formed on the substrate and including an auxiliary capacitor and a switching element which is located close to each of intersections of the scanning lines and the signal lines; a regulation pad group provided to supply or output a signal to the scanning lines and the signal lines; a line made of metal and formed inside the substrate and along a periphery thereof; and a mark formed within a width region of the line by extracting part of a metal portion.

According to other aspect of the present invention, there is provided a method of inspecting an array substrate which includes a substrate on which a plurality of scanning lines and a plurality of signal lines are arranged so as to intersect each other, pixel sections formed on the substrate and including an auxiliary capacitor and a switching element which is located close to each of intersections of the scanning lines and the signal lines, a specified pad group provided to supply or output a signal to the scanning lines and the signal lines, and a line made of metal and formed on and inside the substrate and along a periphery thereof, the method comprising: extracting part of a metal portion from a width region of the line formed on the substrate to form a mark within the width region of the line; scanning an electron beam over the array substrate to detect the mark; and controlling a scanning area of the electron beam based on positional information of the detected mark.

According to other aspect of the present invention, there is provided a method of manufacturing an array substrate which includes a substrate on which a plurality of scanning lines and a plurality of signal lines are arranged so as to intersect each other, pixel sections formed close to each other intersections of the scanning lines and the signal lines on the substrate and including a switching element and an auxiliary capacitor, a specified pad group provided to supply or output a signal to the scanning lines and the signal lines, and a line made of metal and formed on and inside the substrate and along a periphery thereof, the method comprising: forming the array substrate on a mother substrate; and extracting part of a metal portion from a width region of the line formed on the array substrate to form a mark within the width region of the line.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a schematic plan view showing a power supply line of an array substrate according to an embodiment of the present invention;

FIG. 2 is a schematic sectional view of a liquid crystal display panel having an array substrate;

FIG. 3 is a perspective view showing part of the liquid crystal display panel shown in FIG. 2;

FIG. 4 is a plan view showing an example of arrangement of array substrates formed using a mother substrate;

FIG. 5 is a schematic plan view of each of the array substrates shown in FIG. 4;

FIG. 6 is an enlarged schematic plan view of part of a pixel region of the array substrate shown in FIG. 5;

FIG. 7 is a schematic sectional view of a liquid crystal display panel with the array substrate shown in FIG. 6;

FIG. 8 is a basic diagram of a configuration of an electron beam tester according to the embodiment of the present invention;

FIG. 9 is a schematic diagram of a configuration of an inspecting apparatus of array substrates, which includes the electron beam tester according to the embodiment of the present invention; and

FIG. 10 is an example of a flowchart illustrating a method of inspecting array substrates.

### DETAILED DESCRIPTION OF THE INVENTION

Array substrate, a method of inspecting the array substrate and a method of manufacturing the array substrate according to an embodiment of the present invention will be described with reference to the drawings. First, a liquid crystal display panel having an array substrate will be described.

As shown in FIGS. 2 and 3, a liquid crystal display panel includes an array substrate 101, an opposed substrate 102 arranged opposite to the array substrate with a given gap therebetween, and a liquid crystal layer 103 sandwiched between both the substrates. The array substrate 101 and counter substrate 102 which are held by the plurality of columnar spacers 127 such that they arranged opposite to each other with a predetermined gap therebetween. The array substrate 101 and the opposed substrate 102 are bonded together with a sealing member 160 at their edge portions. A liquid crystal injection port 161 is formed in part of the sealing member 160 and sealed with a sealant 162.

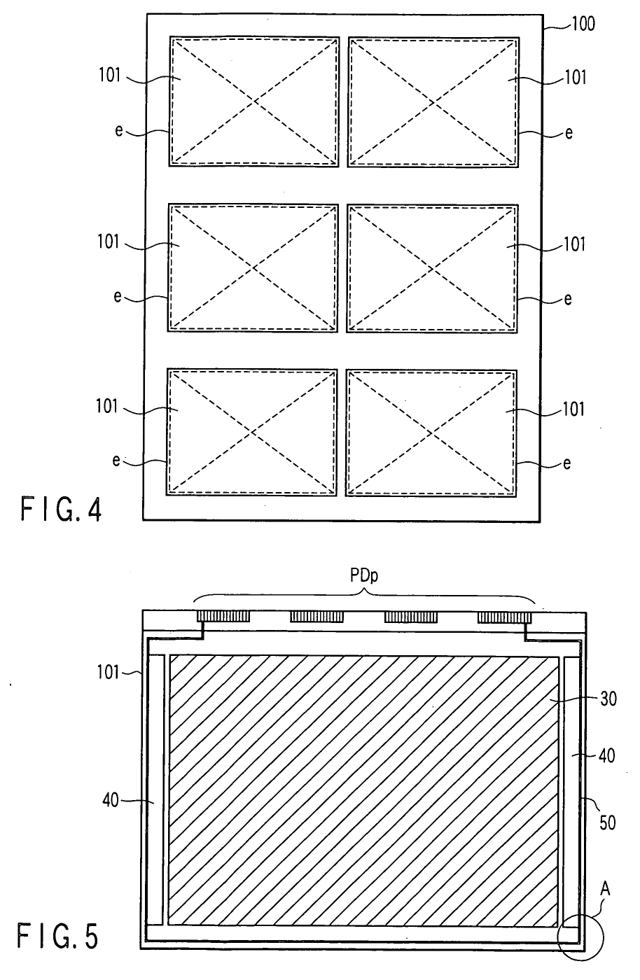

The array substrate 101 will be described in detail with reference to FIG. 4. FIG. 4 shows a mother substrate 100 the size of which is larger than that of the array substrate 100. In the example of FIG. 4, six array substrates 101 are configured using the mother substrate. The array substrates 101 are generally formed on the surface of the mother substrate 100. The array substrates 101 are arranged at specified intervals. Here is the description of a configuration of one of the array substrates 101.

As illustrated in FIG. 5, the array substrate 101 includes a rectangular pixel region 30 located almost in the central part of the substrate. A scanning line driving circuit 40 is located at an end portion of the array substrate 101 and outside the pixel region 30. The array substrate 101 has a regulation pad group PDₚ and the regulation pad group PDₚ is arranged along one of edge lines of the array substrate. The regulation pad group PDₚ is provided to supply a drive signal or a video signal to the array substrate from outside. The regulation pad group PDₚ is also provided to input/output a signal for inspection using an electron beam tester (hereinafter referred to as an EB tester). A line 50 for a power supply (hereinafter referred to as a power supply line) connected to the specified pad group PDₚ is formed on the periphery of the array substrate 101. A voltage that is applied to the opposed electrode of the opposed substrates 102, described later, is input to the power supply line 50.

A plurality of array substrates are formed on the mother substrate and arranged along the edge e (FIG. 4). In the post process, the array substrates are stuck to the opposed substrates 102 and then the mother substrate is cut at the edge, with the result that a plurality of cells are cut out and separated from one another.

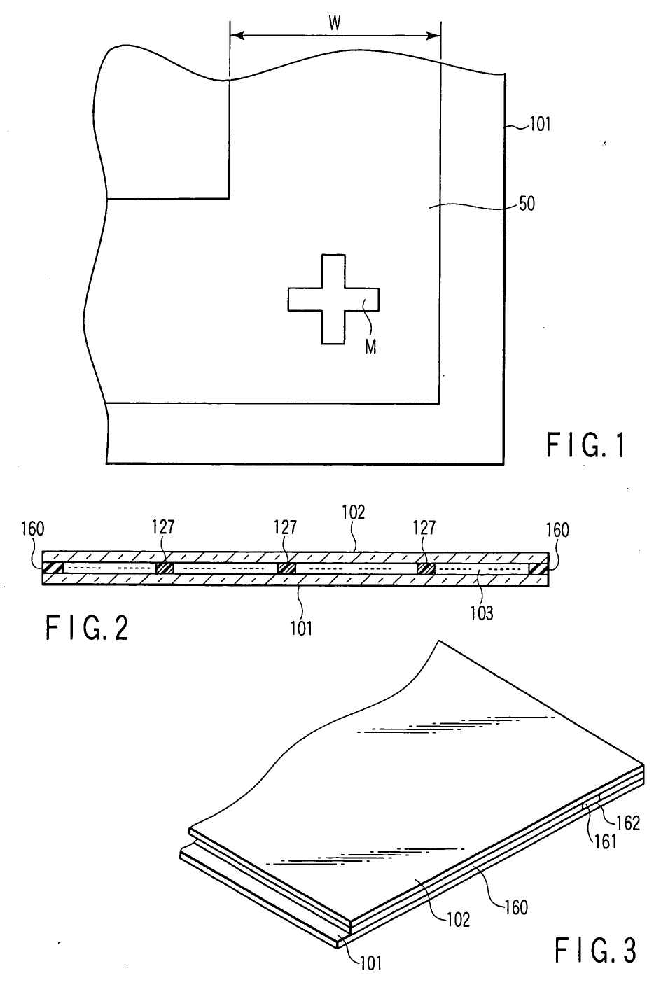

The power supply line 50 will be described with reference to FIG. 1 by enlarging a circled portion A shown in FIG. 5. The power supply line 50 has a given-width area W as a metal portion. In the given-width area W of the power supply line 50, for example, a cross mark M is formed as a mark. The cross mark M is formed by removing part of the metal portion in advance.

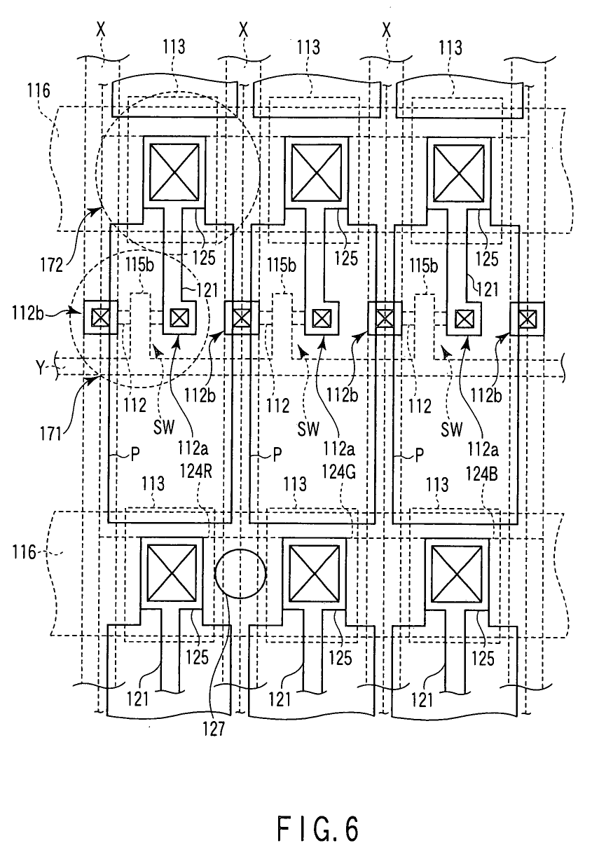

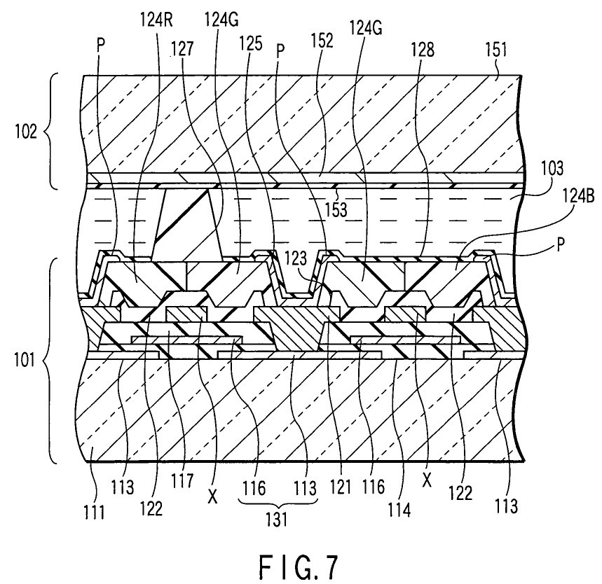

The pixel region 30 shown in FIG. 5 will be described further with reference to FIGS. 6 and 7 by extracting its part. FIG. 6 is an enlarged plan view of the pixel region 30 of the array substrate, and FIG. 7 is an enlarged sectional view of the pixel region of the liquid crystal display panel. The array substrate 101 includes a substrate 111 as a transparent insulation substrate such as a glass substrate. In the pixel region 30, a plurality of signal lines X and a plurality of scanning lines Y are formed in matrix on the substrate 111. A thin-film transistor (hereinafter referred to as TFT) SW (see the portion surrounded by circle 171 in FIG. 6) is provided close to each of intersections of the signal lines and scanning lines as a switching element.

The TFT SW includes a semiconductor film 112 having source/drain regions 112a and 112b formed of polysilicon and a gate electrode 115b that corresponds to an elongated portion of a scanning line Y. When the signal lines X and scanning lines Y are formed, the power supply line 50 (see FIGS. 1 and 5) is formed. These lines are formed of the same material.

A plurality of auxiliary capacitive lines 116 are formed in a striped manner on the substrate 111 to form auxiliary capacitive elements 131, and extend in parallel with the scanning lines Y. A pixel electrode P is formed in this section. (see the portion surrounded by circle 172 in FIG. 6 and FIG. 7)

If described in detail, semiconductor films 112 and auxiliary capacitive lower electrodes 113 are formed on the substrate 111, and a gate insulation film 114 is deposited on the substrate including the semiconductor films and the auxiliary capacitive lower electrodes 113. Like the semiconductor film 112, the auxiliary capacitive lower electrodes 113 are formed of polysilicon. Scanning lines Y, gate electrodes 115b and auxiliary capacitive lines 116 are formed on the gate insulation film 114. The auxiliary capacitive lines 116 and auxiliary capacitive lower electrodes 113 are arranged opposite to each other with the gate insulation film 114 therebetween. An interlayer insulation film 117 is deposited on the gate insulation film 114 including the scanning lines Y, gate electrodes 115b and auxiliary capacitive lines 116.

Contact electrodes 121 and signal lines X are formed on the interlayer insulation film 117. Each contact electrode 121 is connected through a respective contact hole to the source/drain region 112a of the respective semiconductor film 112 and the pixel electrode P. The contact electrode 121 is connected to the auxiliary capacitive lower electrode 113. Each signal line X is connected to the source/drain region 112b of the respective semiconductor film 112 through a respective contact hole.

A protecting insulation film 122 is formed on the contact electrodes 121, signal lines X and interlayer insulation film 117. Further, green-colored layers 124G, red-colored layers 124R and blue-colored layers 124B are arranged adjacent to each other in a striped manner on the protecting insulation film 122. The colored layers 124G, 124R and 124B make up a color filter.

The pixel electrodes P are formed on their respective colored layers 124G, 124R and 124B by transparent conductive film such as ITO (indium tin oxide). Each of the pixel electrodes P is connected to the contact electrode 121 through a contact hole 125 formed in the colored layers and protecting insulation film 122. The peripheries of the pixel electrodes P overlap the auxiliary capacitive lines 116 and signal lines X. The auxiliary capacitive element 131 connected to the pixel electrodes P functions as auxiliary capacitor store electric charge.

The columnar spacer 127 is formed on the colored layers 124R and 124G. A plurality of columnar spacers 127 are formed on the colored layers at a desired density though all of them are not shown. An alignment film 128 is formed on the colored layers 124G, 124R and 124B and the pixel electrodes P.

The opposed substrate 102 has a substrate 151 as a transparent insulation substrate. An opposed electrode 152 made of transparent material such as an ITO and an alignment film 153 are formed in sequence on the substrate 151.

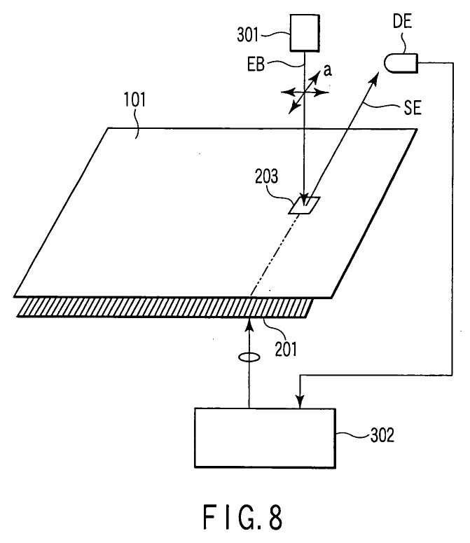

A method of inspecting the array substrate 101 using an EB tester will be described with reference to FIG. 8. Here is a description of detection of secondary electrons that depend upon the voltage of a pixel section 203 formed on the substrate and including the TFT SW, auxiliary capacitive elements 131 and pixel electrodes P.

First, a plurality of probes connected to a signal generator and a signal analyzer 302 are connected to a plurality of pads 201. The drive signals output from the signal generator and the signal analyzer 302 are supplied to the pixel section 203 through the probes and the pads 201. After the drive signals are supplied to the pixel section 203, the pixel section is irradiated with an electron beam EB from an electron beam source 301. With this irradiation, a secondary electron SE that represents the voltage of the pixel section 203 is emitted and detected by an electron detector DE. The secondary electron SE is proportionate to the voltage of an area from which the electron is emitted.

Information of the secondary electron detected by the electron detector DE is sent to the signal generator and the signal analyzer 302 in order to analyze the pixel sections 203. The variation in voltage indicates the state of the pixel sections 203. It is thus possible to inspect the state of the voltage of the pixel electrodes P of each of the pixel sections 203. In other words, when the pixel sections 203 are defective, the EB tester can detect the defect. The inspection of this embodiment means detecting not only a defect of a pixel electrode P in itself but also a defect of an element associated with the pixel electrode, such as a TFT SW connected to the pixel electrode and an auxiliary capacitive element.

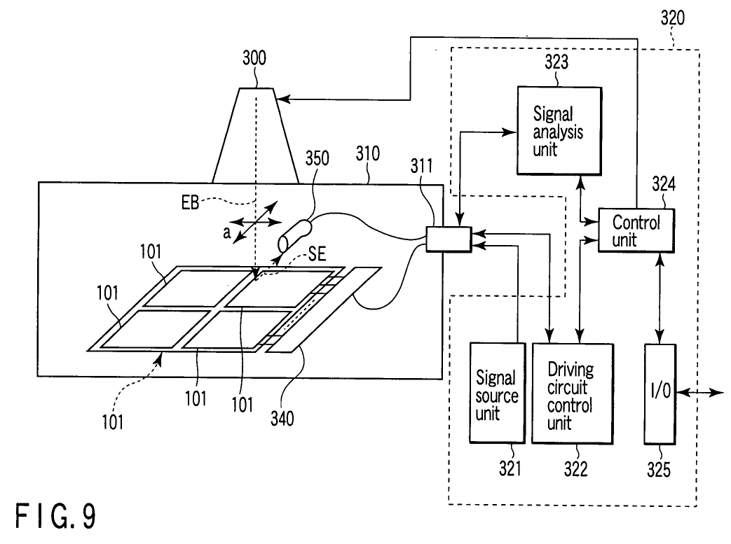

A method of inspecting the array substrate 101 using the EB tester and an apparatus for inspecting the array substrate will be described with reference to FIG. 9. First, the configuration of the inspecting apparatus used for inspecting the array substrate 101 will be described. An electrical tester and an electron beam tester are provided integrally with the inspecting apparatus as one component. A vacuum chamber 310 is equipped with an electron beam scanner 300. The array substrate 101 can be held in the vacuum chamber 310 and removed therefrom. An electron detector 350 is provided in the vacuum chamber 310. A probe unit 340 is arranged in the vacuum chamber 310, and the probe unit 340 has a plurality of probes that can be brought into contact with their corresponding pads of the array substrate 101. This control can be performed by a robot, not shown, with high precision.

A sealing connector 311 is provided on the sidewall of the vacuum chamber 310. The sealing connector 311 brings the internal probe unit 340, the electron detector 350, etc. into contact with their corresponding external units while keeping the vacuum chamber 310 hermetic. A control device 320 is provided outside the vacuum chamber 310. The control device 320 includes a signal source unit 321, a driving circuit control unit 322, a signal analysis unit 323, a control unit 324 that controls these units, and an input/output unit 325.

The control unit 324 can control the driving circuit control unit 322 to inspect a driving circuit on the array substrate 101 through the probe unit 340. The driving circuit control unit 322 can drive the elements on the array substrate 101 through the regulation pad group on the array substrate 101. At this time, the signal generated from the signal source unit 321 is also supplied to the regulation pad group on the array substrate to electrically charge the auxiliary capacitors of the pixel sections.

The driving circuit control unit 322 can control the electron beam scanner 300 to scan over the pixel section of the array substrate 101. The secondary electrons emitted from the pixel section are detected by the electron detector 350 and its detection information is sent to the signal analysis unit 323. The signal analysis unit 323 analyzes the detection information from the electron detector 350 and refers to the positional information (address of a detected pixel) from the control unit 324 to determine the state of the pixel section.

The pixel section of the array substrate 101 is inspected using the inspecting apparatus described above. It is necessary to understand a relationship in relative position between the array substrate 101 and the electron beam source 301 prior to the inspection. Based on information of the relationship in relative position, an electron beam needs to be deflected appropriately and each of very small pixel electrodes P that exist in the array substrate 101 needs to be irradiated with an electron beam accurately. A method of detecting the relationship in relative position will be described below.

The array substrate 101 is arranged roughly in the vacuum chamber 310. The regulation pad group PDₚ of the array substrate 101 and the probe unit 340 of the inspecting apparatus are connected to each other. The array substrate 101 is supplied with a drive signal and the pixel electrodes P are charged electrically. At the same time, the power supply line 50 of the array substrate 101 is also supplied with a signal and charged electrically. An electron beam is applied in advance to an area close to the mark M formed on the power supply line 50 and its secondary electron is detected by the electron detector 350, thereby detecting a portion not charged electrically, or a position of the mark M. With reference to this positional information, the degree of deflection of electron beams required when the relative position is finely adjusted and the electron beam is scanned is determined and then the electron beam is accurately applied to each of the pixel electrodes P, thus performing the inspection.

The control unit 324 can control the scanning area of electron beams with reference to the position of the mark M.

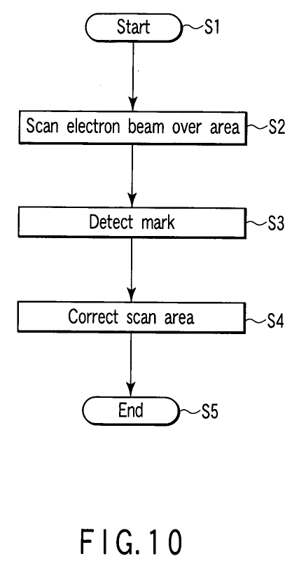

FIG. 10 is an example of a flowchart set for the control unit 324 and the flowchart shows a process of detecting the mark M. When alignment starts (step S1), the control unit 324 controls the electron beam scanner 300 and scans a beam over an area close to the mark M (step S2). The secondary electron SE is detected by the electron detector 350, its detection information is analyzed by the signal analysis unit 323, and its analysis result is sent to the control unit 324.

When the mark M is detected (step S3), the control unit 324 corrects the beam scan area (step S4) to reliably scan the electron beam over the array substrate. When the alignment is completed (step S5), the actual inspection starts. The inspection has various contents.

According to the array substrate and the method of inspecting the array substrate as described above, the mark M is formed in the array substrate 101 to make it possible to arrange array substrates on the surface of the mother substrate 100 at very narrow intervals. Thus, the number of array substrates formed on the surface of the mother substrate 100 can be increased. For example, this invention is effective in forming array substrates of different types on the mother substrate 100. Since no alignment mark is formed outside the array substrate 101, a pattern such as a TEG (Test Element Group) can be formed in an area outside the array substrate.

Since the position of the mark M formed in the array substrate 101 is detected by the EB tester, the position of the pixel section on the substrate can be grasped. Therefore, the state of the pixel section can be inspected while grasping the position of the pixel section in advance. Since the mark M is provided on the power supply line 50 of the array substrate 101, it can be done without increasing the manufacturing steps in number.

This invention is not limited to the above-described embodiment, but various modifications can be made within the scope of the invention. For example, the shape of the above mark M is not limited to a cross but can be a triangle, a rectangle and the like. In the present embodiment, the mark M is formed on the power supply line 50 for applying a voltage to the opposed electrode when a product is completed. However, a line for applying a power supply voltage such as VDD and VSS to the driving circuit provided on the array substrate can be formed. Moreover, it is not only on the power supply line but also on other different lines that the mark M is formed.

What is claimed is:

1. An array substrate comprising:
a substrate on which a plurality of scanning lines and a plurality of signal lines are arranged so as to intersect each other;
pixel sections formed on the substrate and including an auxiliary capacitor and a switching element which is located close to each of intersections of the scanning lines and the signal lines;
a regulation pad group provided to supply or output a signal to the scanning lines and the signal lines;
a line made of metal and formed inside the substrate and along a periphery thereof; and
a mark formed within a width region of the line by extracting part of a metal portion.

2. The array substrate according to claim 1, wherein the mark is a cross.

3. The array substrate according to claim 1, wherein the line on which the mark is formed is a power supply line.

4. A method of inspecting an array substrate which includes a substrate on which a plurality of scanning lines and a plurality of signal lines are arranged so as to intersect each other, pixel sections formed on the substrate and including an auxiliary capacitor and a switching element which is located close to each of intersections of the scanning lines and the signal lines, a specified pad group provided to supply or output a signal to the scanning lines and the signal lines, and a line made of metal and formed on and inside the substrate and along a periphery thereof, the method comprising:
extracting part of a metal portion from a width region of the line formed on the substrate to form a mark within the width region of the line;
scanning an electron beam over the array substrate to detect the mark; and
controlling a scanning area of the electron beam based on positional information of the detected mark.

5. The method of inspecting an array substrate according to claim 4, further comprising
irradiating the pixel sections in the scanning area with an electron beam to determine whether the pixel sections in the scanning area irradiated with the electron beam is defective.

6. A method of manufacturing an array substrate which includes a substrate on which a plurality of scanning lines and a plurality of signal lines are arranged so as to intersect each other, pixel sections formed close to each of intersections of the scanning lines and the signal lines on the substrate and including a switching element and an auxiliary capacitor, a specified pad group provided to supply or output a signal to the scanning lines and the signal lines, and a line made of metal and formed on and inside the substrate and along a periphery thereof, the method comprising:
forming the array substrate on a mother substrate; and
extracting part of a metal portion from a width region of the line formed on the array substrate to form a mark within the width region of the line.
